(19) United States
(12) Patent Application Publication
(10) Pub. No.: US 2024/0128714 A1
(43) Pub. Date: Apr. 18, 2024

(54) VCSEL DIODE AND VCSEL DIODE ARRAY HAVING COMMON ANODE STRUCTURE

(71) Applicant: Korea Photonics Technology Institute, Gwangju (KR)

(72) Inventor: Keon Hwa LEE, Gwangju (KR)

(73) Assignee: Korea Photonics Technology Institute, Gwangju (KR)

(21) Appl. No.: 18/485,436

(22) Filed: Oct. 12, 2023

(30) Foreign Application Priority Data
Oct. 14, 2022 (KR) 10-2022-0132557

(51) Int. Cl. H01S 5/042; H01S 5/062; H01S 5/183; H01S 5/42

(52) U.S. Cl. CPC H01S 5/04256; H01S 5/06203; H01S 5/18313; H01S 5/18361; H01S 5/423

(57) ABSTRACT

Disclosed are a VCSEL diode and a VCSEL diode array having a common anode structure. An aspect of the present disclosure provides the VCSEL diode and the VCSEL diode array, which smoothly perform an operation and improve the quality of output light because the VCSEL diode and the VCSEL diode array have a common anode structure.

### CROSS-REFERENCE TO RELATED APPLICATIONS

This application claims priority to Korean Patent Application No. 10-2022-0132557 filed on Oct. 14, 2022, the entire contents of which are herein incorporated by reference.

This patent is the results of research that was carried out by the support (a unique project number: 1415185090, a detailed project number: 20018154, a project name: Development of Multi-Axis Assembly System for Curved Free-Form Electronics) of Korea Evaluation Institute of Industrial Technology by the finances of the government of the Republic of Korea (Ministry of Trade, Industry and Energy) in 2023.

### BACKGROUND

### 1. Technical Field

The present disclosure relates to a VCSEL diode and VCSEL diode array having a common anode structure.

### 2. Related Art

Contents described in this part merely provide background information of the present embodiment, and do not constitute a conventional technology.

In general, a semiconductor laser diode includes an edge emitting laser (hereinafter abbreviated as “EEL”) diode and a vertical cavity surface emitting laser (hereinafter abbreviated as “VCSEL”) diode. The EEL diode has a resonance structure that has a direction parallel to a stack surface of a device, and oscillates a laser beam in the direction parallel to the stack surface. The VCSEL diode has a resonance structure that has a direction vertical to a stack surface of a device, and oscillates a laser beam in the direction vertical to the stack surface of the device.

The VCSEL diode has advantages in that the VCSEL is capable of being implemented to have low power because the VCSEL diode has a shorter light gain length than the EEL diode and that the VCSEL diode is advantageous for mass production because the VCSEL diode is capable of high-density integration.

Furthermore, the VCSEL diode can oscillate a laser beam in a single longitudinal mode, and can be tested on a wafer. Furthermore, the VCSEL diode is capable of high-speed modulation and can oscillate a circular beam. Accordingly, the VCSEL diode can be easily coupled with an optical fiber and can be implemented as a two-dimensional surface array.

The VCSEL diode has been basically used as a light source within an optical device for optical communication, an optical interconnection, and optical pick-up. However, recently, the range of use of the VCSEL diode is expanded up to a light source within an image forming device, such as a LiDAR, face recognition, motion recognition, an augmented reality (AR), or virtual reality (VR) device. As described above, the VCSEL diode is used in various fields. Accordingly, it is necessary to properly manufacture a VCSEL diode chip or a VCSEL diode array depending on the use of the VCSEL diode.

When the VCSEL diode is used in a LiDAR device, a plurality of VCSEL diodes forms one channel in order to increase its output. The VCSEL diodes are implemented in the form of an array in which one or more such channels are disposed.

The LiDAR device needs to output light having strong intensity up to a remote distance in order to detect an object. Furthermore, if an object to be detected is a person, the duration of the light output by the LiDAR device needs to be minimized in order to protect the eyeballs of the object. That is, a light source (or a VCSEL diode array) within the LiDAR device needs to output light that has strong intensity and that has a form of a pulse having short duration. To this end, a relatively high operating voltage needs to be applied to the light source within the LiDAR device.

A conventional VCSEL diode array (light source) within a LiDAR device has been implemented in a form in which an n type substrate and an n type electrode are disposed at the bottom of the VCSEL diode array and a cathode is used in common (i.e., a common cathode). Operating voltages are individually applied to VCSEL diodes between channels within such a VCSEL diode array. A single driver field effect transistor (FET) is connected to the VCSEL diodes between the channels in common, and the on and off of the VCSEL diodes are controlled. However, an inverse voltage attributable to the driver FET is also applied to VCSEL diodes to which the operating voltage is not applied (i.e., not selected) because the single driver FET is electrically connected to all the VCSEL diodes within the VCSEL diode array as described above. This raises a problem in that the lifespan of the VCSEL diode is reduced. Furthermore, when a VCSEL diode of another channel is selected and operated, an operating voltage to which the inverse voltage has been added, in addition to the existing operating voltage that is commonly applied, needs to be applied. Accordingly, in the case of the conventional VCSEL diode array, the size of an operating voltage that needs to be applied is unfavorably increased.

### SUMMARY

An embodiment of the present disclosure is directed to providing a VCSEL diode and a VCSEL diode array, which have a common anode structure, operate smoothly, and improve the quality of output light.

According to an aspect of the present disclosure, there is provided a vertical cavity surface emitting laser (VCSEL) diode, including an n type substrate, a high-doping n type layer and a high-doping p type layer sequentially grown on the n type substrate, a p type reflection part grown on the high-doping p type layer and including a plurality of distributed Bragg reflector (DBR) pairs, an oxidation layer grown on the p type reflection part and configured to determine characteristics of a laser to be output and the diameter of an opening, an active layer grown on the oxidation layer and configured to oscillate light by recombining holes and electrons, an n type reflection part grown on the active layer and including a plurality of DBR pairs, a first metal layer grown on the n type reflection part and configured to supply power to the n type reflection part, and a second metal layer grown on one surface of the n type substrate and configured to supply power to the p type reflection part.

According to an aspect of the present disclosure, the VCSEL diode further includes a p type layer grown between the high-doping p type layer and the p type reflection part.

According to an aspect of the present disclosure, the VCSEL diode further includes a p type layer grown between the oxidation layer and the active layer.

According to an aspect of the present disclosure, there is provided a vertical cavity surface emitting laser (VCSEL) diode, including an n type substrate, a first high-doping n type layer and a first high-doping p type layer sequentially grown on the n type substrate, a p type reflection part grown on the high-doping p type layer and including a plurality of distributed Bragg reflector (DBR) pairs, a first oxidation layer grown on the p type reflection part and configured to determine characteristics of a laser to be output and the diameter of an opening, a first active layer grown on the first oxidation layer and configured to oscillate light by recombining holes and electrons, a second high-doping n type layer and a second high-doping p type layer sequentially grown on the first active layer, a second oxidation layer grown on the second high-doping p type layer and configured to determine characteristics of a laser to be output and the diameter of an opening, a second active layer grown on the second oxidation layer and configured to oscillate light by recombining holes and electrons, an n type reflection part grown on the second active layer and including a plurality of DBR pairs, a first metal layer grown on the n type reflection part and configured to supply power to the n type reflection part, and a second metal layer grown on one surface of the n type substrate and configured to supply power to the p type reflection part.

According to an aspect of the present disclosure, the VCSEL diode further includes a p type layer grown between the first oxidation layer and the first active layer.

According to an aspect of the present disclosure, the VCSEL diode further includes an n type layer grown between the first active layer and the second high-doping n type layer.

According to an aspect of the present disclosure, there is provided a vertical cavity surface emitting laser (VCSEL) diode, including a p type substrate, a p type reflection part grown on the p type substrate and including a plurality of distributed Bragg reflector (DBR) pairs, an oxidation layer grown on the p type reflection part and configured to determine characteristics of a laser to be output and the diameter of an opening, an active layer grown on the oxidation layer and configured to oscillate light by recombining holes and electrons, an n type reflection part grown on the active layer and including a plurality of DBR pairs, a first metal layer grown on the n type reflection part and configured to supply power to the n type reflection part, and a second metal layer grown on one surface of the p type substrate and configured to supply power to the p type reflection part.

According to an aspect of the present disclosure, the active layer is implemented as a multi-quantum well.

According to an aspect of the present disclosure, the VCSEL diode further includes a p type layer grown between the oxidation layer and the active layer.

According to an aspect of the present disclosure, there is provided a vertical cavity surface emitting laser (VCSEL) diode, including a p type substrate, a p type reflection part grown on the p type substrate and including a plurality of distributed Bragg reflector (DBR) pairs, a first oxidation layer grown on the p type reflection part and configured to determine characteristics of a laser to be output and the diameter of an opening, a first active layer grown on the first oxidation layer and configured to oscillate light by recombining holes and electrons, a second high-doping n type layer and a second high-doping p type layer sequentially grown on the first active layer, a second oxidation layer grown on the second high-doping p type layer and configured to determine characteristics of a laser to be output and the diameter of an opening, a second active layer grown on the second oxidation layer and configured to oscillate light by recombining holes and electrons, an n type reflection part grown on the second active layer and including a plurality of DBR pairs, a first metal layer grown on the n type reflection part and configured to supply power to the n type reflection part, and a second metal layer grown on one surface of the p type substrate and configured to supply power to the p type reflection part.

According to an aspect of the present disclosure, the active layer is implemented as a multi-quantum well.

According to an aspect of the present disclosure, the VCSEL diode further includes an n type layer grown between the first active layer and the second high-doping n type layer.

According to an aspect of the present disclosure, there is provided a vertical cavity surface emitting laser (VCSEL) diode, including a p type substrate, a first high-doping p type layer and a first high-doping n type layer sequentially grown on the p type substrate, a first n type reflection part grown on the high-doping n type layer and including a plurality of distributed Bragg reflector (DBR) pairs, a second high-doping n type layer and a second high-doping p type layer sequentially grown on the first n type reflection part, a first oxidation layer grown on the second high-doping p type layer and configured to determine characteristics of a laser to be output and the diameter of an opening, a first active layer grown on the first oxidation layer and configured to oscillate light by recombining holes and electrons, a second n type reflection part grown on the first active layer and including a plurality of DBR pairs, a first metal layer grown on the second n type reflection part and configured to supply power to the n type reflection part, and a second metal layer grown on one surface of the p type substrate and configured to supply power to the p type reflection part.

According to an aspect of the present disclosure, the first n type reflection part includes a larger number of DBR pairs than the second n type reflection part.

According to an aspect of the present disclosure, the VCSEL diode further includes a p type layer grown between the second high-doping p type layer and the oxidation layer.

According to an aspect of the present disclosure, there is provided a VCSEL diode array, including a plurality of channels in each of which the VCSEL diode is connected in parallel in a plural number and a plurality of driver FETs each connected to the second metal layer of the VCSEL diode within each channel and configured to determine whether each channel will be operate, wherein the same operating power is applied to the first metal layers of all the VCSEL diodes within each channel.

As described above, according to an aspect of the present disclosure, there are advantages in that an operation is smooth and the quality of output light can be improved through the common anode structure.

### BRIEF DESCRIPTION OF THE DRAWINGS

FIG. 1 a circuit diagram of a VCSEL diode array according to an embodiment of the present disclosure.

FIG. 2 is a cross-sectional view of a VCSEL diode according to a first embodiment of the present disclosure.

FIG. 3 is a cross-sectional view of a VCSEL diode according to a second embodiment of the present disclosure.

FIG. 4 is a cross-sectional view of a VCSEL diode according to a third embodiment of the present disclosure.

FIG. 5 is a cross-sectional view of a VCSEL diode according to a fourth embodiment of the present disclosure.

FIG. 6 is a cross-sectional view of a VCSEL diode according to a fifth embodiment of the present disclosure.

FIG. 7 is a cross-sectional view of VCSEL diodes within different channels of a VCSEL diode array according to an embodiment of the present disclosure.

### DETAILED DESCRIPTION

Hereinafter, embodiments of the present disclosure are described in detail with reference to the accompanying drawings so that a person having ordinary knowledge in the art to which the present disclosure pertains may easily practice the embodiments. However, the present disclosure may be implemented in various different forms and is not limited to the embodiments described herein. Furthermore, in the drawings, in order to clarify a description of the present disclosure, parts not related to the description are omitted, and the same reference numbers are used to refer to the same or similar parts throughout the specification.

Throughout this specification, when it is described that one component is “connected” to the other component, the one component may be “directly connected” to the other component or may be “indirectly connected” to the other component through a third component. Furthermore, when it is said that one component “includes” the other component, the word “include” will be understood to imply the inclusion of stated components but not the exclusion of any other components, unless explicitly described to the contrary, and should be understood that it does not exclude the possible existence or addition of one or more other characteristics, numbers, steps, operations, components, parts, or combinations of them in advance.

The following embodiments are detailed descriptions for helping understanding of the present disclosure, and do not limit the scope of a right of the present disclosure. Accordingly, an invention having the same range in which the same function as that of the present disclosure is performed may also belong to the scope of a right of the present disclosure.

Furthermore, each construction, process, procedure, or method included in each embodiment of the present disclosure may be shared within a range in which the constructions, processes, procedures, or methods do not contradict each other technically.

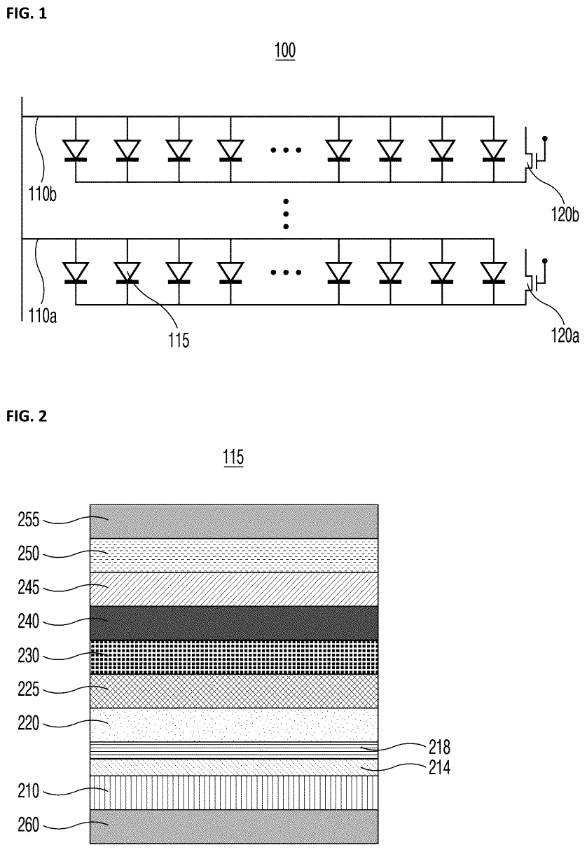

FIG. 1 a circuit diagram of a VCSEL diode array 100 according to an embodiment of the present disclosure.

Referring to FIG. 1, the VCSEL diode array 100 according to an embodiment of the present disclosure includes one or more VCSEL diode channels 110 (e.g., 100a and 100b) and one or more driver FETs 120 (e.g., 120a and 120b).

The VCSEL diode array 100 includes the one or more VCSEL diode channels 110. Each VCSEL diode channel 110 has one end applied with an operating voltage V H and has the other end connected to the driver FET 120. Whether each VCSEL diode channel 110 will operate is controlled by the driver FET 120. In this case, one ends of the respective VCSEL diode channels 110 are connected in common, and the same operating power is applied to all the VCSEL diode channels 110. Whether each VCSEL diode channel 110 will operate is determined based on whether each driver FET 120 connected to each VCSEL diode channel becomes on or off.

The VCSEL diode channel 110 includes a plurality of VCSEL diodes 115 that are connected in parallel. The cathode of each VCSEL diode 115 is disposed toward the driver FET 120 so that the anode of each VCSEL diode 115 is directed toward one end of the VCSEL diode channel. Accordingly, the VCSEL diode array 100 has a characteristic in which the anodes of all the VCSEL diodes within the VCSEL diode array 100 are common.

The following effects are obtained because the anodes of VCSEL diodes within each channel are common, and different driver FETs 120 are connected to different channels. One driver FET is not connected to all channels, but different driver FETs 120 are connected to channels, respectively. Accordingly, although another second channel operates while any one first channel operates as in a conventional technology, the second channel is not influenced by the driver FET of the first channel. Accordingly, although the same operating power (i.e., the size of an inverse voltage is not added) as that of the first channel is applied to the second channel, the second channel can also operate smoothly.

Furthermore, an unnecessary reduction in the lifespan of VCSEL diodes within a channel that does not operate can also be prevented because a continuous inverse voltage is not applied to channels that do not operate.

Each VCSEL diode 115 has structures illustrated in FIGS. 2 to 6 so that the VCSEL diode array 100 or each channel 110 within the VCSEL diode array has a common anode structure.

FIG. 2 is a cross-sectional view of a VCSEL diode 115 according to a first embodiment of the present disclosure.

Referring to FIG. 2, the VCSEL diode 115 according to the first embodiment of the present disclosure includes an n type substrate 210, a high-doping n type layer 214, a high-doping p type layer 218, a p type layer 220, a p type reflection layer 225, an oxidation layer 230, an active layer 240, an n type reflection layer 245, an n type contact layer 250, a first n type metal layer 255, and a second n type metal layer 260.

The n type substrate 210 supports each component of the VCSEL diode 115. The n type substrate 210 has a characteristic in which it has relatively excellent electrical conductivity compared to a p type substrate. The n type substrate 210 may have a flexible characteristic and may have a rigid characteristic.

The high-doping n type layer 214 and the high-doping p type layer 218 are sequentially grown on the n type substrate 210. The layers 214 and 218 may be implemented as n++ and p++ layers, for example. Impurities of 1*10¹⁹/cm³ or more are doped into each of the n type layer and the p type layer. As the layers 214 and 218 are grown on the n type substrate 210, the tunneling phenomenon of electrons can occur and layers having a p type can also be grown on the n type substrate 210.

The p type layer 220 is grown on the high-doping p type layer 218, and serves as a buffer for growth and a buffer that smoothes the flow of carriers under the p type layer 220.

The p type reflection layer 225 may be made of a semiconductor material into which a p type dopant has been doped, and may be made of a semiconductor material including aluminum (Al) (e.g., AlGaAs). The p type reflection layer 225 consists of a plurality of distributed Bragg reflector (DBR) pairs. The DBR pair is implemented as a plurality of pairs, each one including a high Al composition layer having a high aluminum (Al) ratio of 80 to 95% and a low Al composition layer having a low Al ratio of 5 to 20%. The p type reflection layer 225 includes a larger number of DBR pairs than the n type reflection layer 245, and has relatively higher reflectivity compared to the n type reflection layer 245. Accordingly, light or a laser that is oscillated by the active layer 240 is oscillated toward the n type reflection layer 245 that has a relatively small number of pairs and that has low reflectivity.

A part that is oxidized through an oxidation process and that has a predetermined length is formed into the oxidation layer 230. Characteristics of a laser that is output and the diameter of an opening are determined by the length of the oxidized part. The oxidation layer 230 may be made of aluminum (Al) having a higher concentration than that of each of the p type reflection layer 225 and the n type reflection layer 245. The higher the aluminum concentration, the higher the oxidation speed. Subsequent oxidation can be selectively performed because the oxidation layer 230 is implemented to have a relatively higher Al concentration than both the reflection layers 225 and 245. For example, the oxidation layer 230 may be implemented by using AlGaAs having an Al ratio of 98% or more, and each of the reflection layers 225 and 245 may be implemented by using AlGaAs having an Al ratio of 0% to 100%.

In particular, the oxidation layer 230 has better characteristics when the oxidation layer 230 has a p type. The oxidation layer 230 may be formed to have a p type like the p type reflection layer 225 because the oxidation layer 230 is formed on the p type reflection layer 225. Accordingly, the oxidation layer 230 has a relatively more excellent characteristic than an oxidation layer having an n type.

The active layer 240 is a layer in which holes generated from the p type reflection layer 225 and electrons generated from the n type reflection layer 245 meet and are recombined. Light is generated from the active layer 240 by the recombination of the electrons and the holes. The active layer 240 may be implemented as a multi-quantum well (MQW), and has a structure in which a well layer (not illustrated) and a barrier layer (not illustrated) having different energy bands are alternately stacked once or more. The well layer (not illustrated)/barrier layer (not illustrated) of the active layer 240 may be made of InGaAs/AlGaAs, InGaAs/GaAs, InGaAs/GaAsP, or GaAs/AlGaAs.

The n type reflection layer 245 may be made of a semiconductor material into which an n type dopant has been doped, and may be made of a semiconductor material including Al (e.g., AlGaAs). Like the p type reflection layer 225, the n type reflection layer 245 consists of a plurality of DBR pairs. As described above, the n type reflection layer 245 has relatively low reflectivity because the n type reflection layer 245 has a relatively smaller number of DBR pairs than the p type reflection layer 225. Accordingly, light or a laser that is oscillated from the active layer 240 is oscillated toward the n type reflection layer 245.

The n type contact layer 250 is grown on the n type reflection layer 245, and connects the n type reflection layer 245 and the first n type metal layer 255.

The first n type metal layer 255 is connected to a (−) electrode, so that the VCSEL diode 115 can be supplied with electrons from the outside.

The second n type metal layer 260 is grown at the bottom (i.e., a direction opposite to the direction in which the high-doping n type layer has been grown) of the n type substrate 210, and is connected to a (+) electrode, so that the VCSEL diode 115 can be supplied with holes from the outside.

As described above, although each layer is grown from the n type substrate 210, the n type substrate can also operate as the anode of the VCSEL diode because the high doping layers 214 and 218 are grown on the n type substrate 210.

Furthermore, the VCSEL diode 115 according to the first embodiment of the present disclosure has a characteristic in which the high doping layers 214 and 218 within the VCSEL diode 115 are not disposed between the reflection layers 225 and 245. As described above, each of the high doping layers 214 and 218 has a characteristic in which each of the high doping layers is doped with impurities having a very high concentration. Accordingly, the absorption of photons occurs in the high doping layers 214 and 218. In general, in order for light to be oscillated from the active layer 230, the light is reflected in each of the p type and n type reflection layers multiple times. Accordingly, if the doping layers 214 and 218 are disposed between the reflection layers 225 and 245, output efficiency of the light is reduced. The VCSEL diode 115 according to the first embodiment of the present disclosure can prevent the reduction of output efficiency of light by not disposing the high doping layers 214 and 218 between the reflection layers 225 and 245.

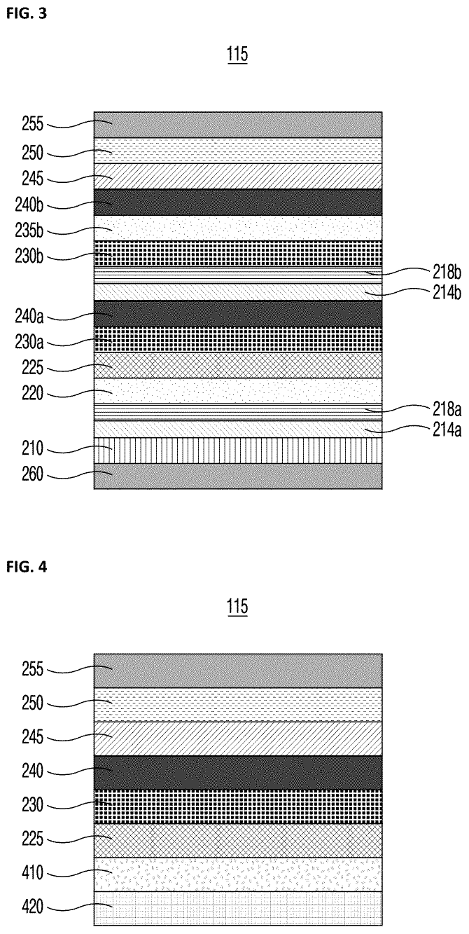

FIG. 3 is a cross-sectional view of a VCSEL diode 115 according to a second embodiment of the present disclosure.

Referring to FIG. 3, the VCSEL diode 115 according to the second embodiment of the present disclosure has the same structure as the VCSEL diode 115 according to the first embodiment of the present disclosure from the second n type metal layer 260 to the active layer 240a and from the n type reflection layer 245 to the first n type metal layer 255 within the VCSEL diode 115, and further includes a high-doping n type layer 214b, a high-doping p type layer 218b, an oxidation layer 230b, and an active layer 240b on the active layer 240a.

The high-doping n type layer 214b, the high-doping p type layer 218b, the oxidation layer 230b, and the active layer 240b are sequentially grown on the active layer 240a. The high-doping n type layer 214b, the high-doping p type layer 218b, the oxidation layer 230b, and the active layer 240b perform the same roles as those of the VCSEL diode 115 according to the first embodiment of the present disclosure.

As described above, the VCSEL diode 115 can form a round-trip gain because the VCSEL diode 115 has a structure in which the plurality of active layer 240 has been vertically stacked and can be implemented as a periodic gain structure.

Furthermore, like the VCSEL diode 115 according to the first embodiment of the present disclosure, the VCSEL diode 115 according to the second embodiment of the present disclosure uses the n type substrate 210 (except the high-doping n type layer 214b and the high-doping p type layer 218b that have been formed to grow both the active layers 240a and 240b having the vertical stack structure), and can have the same effects as the VCSEL diode 115 according to the first embodiment of the present disclosure because the high-doping n type layer 214a and the high-doping p type layer 218a are not disposed between the reflection layers 225 and 245.

FIG. 4 is a cross-sectional view of a VCSEL diode 115 according to a third embodiment of the present disclosure.

Referring to FIG. 4, the VCSEL diode 115 according to the third embodiment of the present disclosure may include a p type substrate 410 and a first p type metal layer 420, instead of the n type substrate 210, the high-doping n type layer 214a, the high-doping p type layer 218a, and the second n type metal layer 260 within the VCSEL diode 115 according to the first embodiment of the present disclosure.

The p type reflection layer 225 can be directly grown on the p type substrate 410 without a need to grow the high-doping n type layer 214a and the high-doping p type layer 218a on the p type substrate 410 because each layer of the VCSEL diode 115 is grown on the p type substrate 410. Accordingly, the growth process of the VCSEL diode 115 can be further simplified.

Furthermore, the first p type metal layer 420 not the second n type metal layer 260 is grown under the p type substrate 410, so that the first p type metal layer 420 is connected to a (+) electrode and the VCSEL diode 115 can be supplied with holes from the outside.

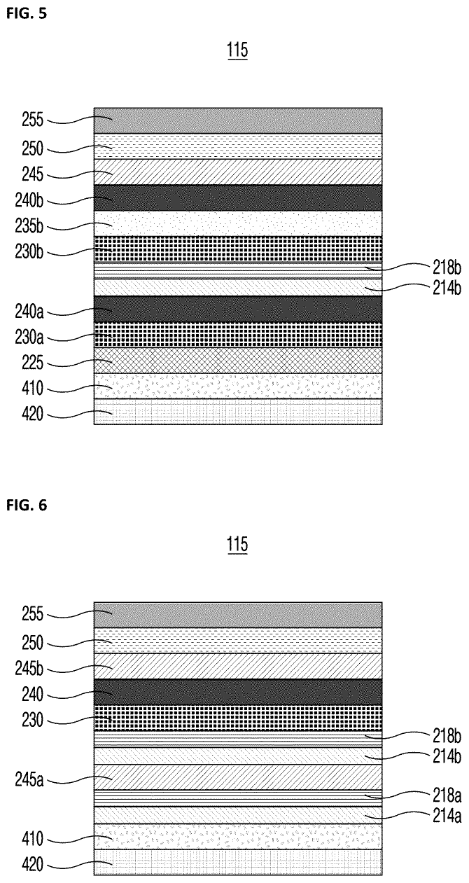

FIG. 5 is a cross-sectional view of a VCSEL diode 115 according to a fourth embodiment of the present disclosure.

Referring to FIG. 5, the VCSEL diode 115 according to the fourth embodiment of the present disclosure may include a p type substrate 410 and a first p type metal layer 420, instead of the n type substrate 210, the high-doping n type layer 214a, the high-doping p type layer 218a, and the second n type metal layer 260 within the VCSEL diode 115 according to the second embodiment of the present disclosure.

The VCSEL diode 115 according to the fourth embodiment of the present disclosure can have a structure in which the plurality of active layer 240 has been vertically stacked while using the p type substrate 410.

FIG. 6 is a cross-sectional view of a VCSEL diode according to a fifth embodiment of the present disclosure.

Referring to FIG. 6, the VCSEL diode 115 according to the fifth embodiment of the present disclosure may include high-doping n type layers 214a and 214b, high-doping p type layers 218a and 218b, and an n type reflection layer 245a, instead of the p type reflection layer 225 within the VCSEL diode 115 according to the third embodiment of the present disclosure. The high-doping n type layer 214a and the high-doping p type layer 218a are sequentially grown on the p type substrate 410 instead of the p type reflection layer 225 so that layers having an n type can be grown.

An n type reflection layer 245a is grown on the high-doping n type layer 214a.

The high-doping n type layer 214b and the high-doping p type layer 218b are grown on the n type reflection layer 245a. An oxidation layer 230 is grown on the high-doping p type layer 218b. The same construction as that of the VCSEL diode 115 according to the third embodiment of the present disclosure is grown.

As described above, the VCSEL diode 115 according to the fifth embodiment of the present disclosure includes the high-doping n type layers 214a and 214b and the high-doping p type layers 218a and 218b. Accordingly, the VCSEL diode 115 according to the fifth embodiment of the present disclosure may include only the n type reflection layers 245a and 245b while each component is grown on the p type substrate 410.

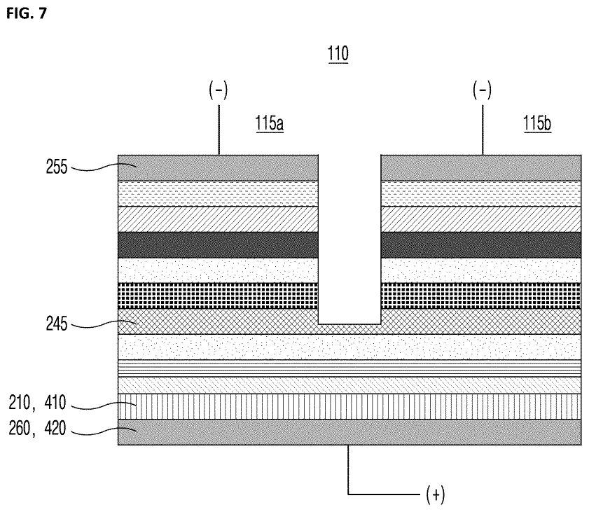

FIG. 7 is a cross-sectional view of VCSEL diodes within different channels of a VCSEL diode array according to an embodiment of the present disclosure.

Referring to FIG. 7, the VCSEL diodes 115 within different channels 110 of the VCSEL diode array have a common anode structure in which at least the substrate 210 or 410 and the metal layer 260 or 420 grown under the substrate 210 or 410 are common. As described above, although the VCSEL diode 115 is implemented according to any one of the first to fifth embodiments, the metal layer 260 or 420 grown under the substrate 210 or 410 operates as an anode (+). Accordingly, the VCSEL diodes 115 that are adjacent to each other within one channel 110 have the common anode structure in which at least the substrate 210 or 410 and the metal layer 260 or 420 are common. The metal layer 255 that operates as a cathode (−) and that is disposed on a side opposite to the anode (+) may be connected to each driver FET 120.

The above description is merely a description of the technical spirit of the present embodiment, and those skilled in the art may change and modify the present embodiment in various ways without departing from the essential characteristic of the present embodiment. Accordingly, the embodiments should not be construed as limiting the technical spirit of the present embodiment, but should be construed as describing the technical spirit of the present embodiment. The technical spirit of the present embodiment is not restricted by the embodiments. The range of protection of the present embodiment should be construed based on the following claims, and all of technical spirits within an equivalent range of the present embodiment should be construed as being included in the scope of rights of the present embodiment.

[Description of reference numerals]

| | |
|---|---|
| 100: VCSEL diode array | 110: VCSEL diode channel |
| 115: VCSEL diode | 120: driver FET |
| 210: n type substrate | 214: high-doping n type layer |
| 218: high-doping p type layer | 220: p type layer |
| 225: p type reflection layer | 230: oxidation layer |
| 240: active layer | 245: n type reflection layer |
| 250: n type contact layer | 255, 260: n type metal layer |
| 410: p type substrate | 420: p type metal layer |

What is claimed is:

1. A vertical cavity surface emitting laser (VCSEL) diode, comprising:
an n type substrate;
a high-doping n type layer and a high-doping p type layer sequentially grown on the n type substrate;
a p type reflection part grown on the high-doping p type layer and comprising a plurality of distributed Bragg reflector (DBR) pairs;
an oxidation layer grown on the p type reflection part and configured to determine characteristics of a laser to be output and a diameter of an opening;
an active layer grown on the oxidation layer and configured to oscillate light by recombining holes and electrons;
an n type reflection part grown on the active layer and comprising a plurality of DBR pairs;
a first metal layer grown on the n type reflection part and configured to supply power to the n type reflection part; and
a second metal layer grown on one surface of the n type substrate and configured to supply power to the p type reflection part.

2. The VCSEL diode of claim 1, further comprising a p type layer grown between the high-doping p type layer and the p type reflection part.

3. The VCSEL diode of claim 1, further comprising a p type layer grown between the oxidation layer and the active layer.

4. The VCSEL diode of claim 1, further comprising:
a second high-doping n type layer and a second high-doping p type layer sequentially grown on the active layer; and
a second oxidation layer grown on the second high-doping p type layer and configured to determine characteristics of a laser to be output and a diameter of an opening.

5. The VCSEL diode of claim 4, further comprising a second active layer grown on the second oxidation layer and configured to oscillate light by recombining holes and electrons.

6. The VCSEL diode of claim 5, wherein the n type reflection part is grown on the second active layer if the second active layer is included in the VCSEL diode.

7. The VCSEL diode of claim 4, further comprising an n type layer grown between the first active layer and the second high-doping n type layer.

8. A vertical cavity surface emitting laser (VCSEL) diode comprising:
a p type substrate;
a p type reflection part grown on the p type substrate and comprising a plurality of distributed Bragg reflector (DBR) pairs;
an oxidation layer grown on the p type reflection part and configured to determine characteristics of a laser to be output and a diameter of an opening;
an active layer grown on the oxidation layer and configured to oscillate light by recombining holes and electrons;
an n type reflection part grown on the active layer and comprising a plurality of DBR pairs;
a first metal layer grown on the n type reflection part and configured to supply power to the n type reflection part; and
a second metal layer grown on one surface of the p type substrate and configured to supply power to the p type reflection part.

9. The VCSEL diode of claim 8, wherein the active layer is implemented as a multi-quantum well.

10. The VCSEL diode of claim 8, further comprising a p type layer grown between the oxidation layer and the active layer.

11. The VCSEL diode of claim 8, further comprising:
a second high-doping n type layer and a second high-doping p type layer sequentially grown on the first active layer;
a second oxidation layer grown on the second high-doping p type layer and configured to determine characteristics of a laser to be output and a diameter of an opening; and
a second active layer grown on the second oxidation layer and configured to oscillate light by recombining holes and electrons.

12. The VCSEL diode of claim 11, wherein the n type reflection part is grown on the second active layer if the second active layer is included in the VCSEL diode.

13. A vertical cavity surface emitting laser (VCSEL) diode array comprising:
a plurality of channels in each of which the plurality of VCSEL diodes according to claim 1 has been connected in parallel; and
a plurality of driver field effect transistors (FETs) each connected to the second metal layer of the VCSEL diode within each channel and configured to determine whether each channel is to operate,
wherein an identical operating voltage is applied to the first metal layers of all the VCSEL diodes within each channel.
